(19) United States
(12) Patent Application Publication
(10) Pub. No.: US 2024/0162123 A1
(43) Pub. Date: May 16, 2024

(54) POWER SEMICONDUCTOR MODULE AND SEMICONDUCTOR DEVICE

(71) Applicant: ROHM CO., LTD., Kyoto-shi (JP)

(72) Inventor: Hideo HARA, Kyoto-shi (JP)

(21) Appl. No.: 18/419,222

(22) Filed: Jan. 22, 2024

Related U.S. Application Data
(63) Continuation of application No. PCT/JP2022/028534, filed on Jul. 22, 2022.

(30) Foreign Application Priority Data
Jul. 29, 2021 (JP) 2021-124283

(51) Int. Cl. H01L 23/495; H01L 23/36

(52) U.S. Cl. CPC H01L 23/49555; H01L 23/36; H01L 23/49575

(57) ABSTRACT

A power semiconductor module includes a first terminal which protrudes from a first body side surface of a module body, and a second terminal which protrudes from a second body side surface. The first terminal includes a first portion which protrudes from the first body side surface, a second portion which extends the first portion beyond a body rear surface on the reverse side from from a body main surface, and a third portion which extends from the second portion. The second terminal includes a first portion which protrudes from the second body side surface, a second portion which extends from the first portion beyond the body rear surface on the reverse side from the body main surface, and a third portion which extends from the second portion.

### BACKGROUND

The present disclosure relates to a power semiconductor module and a semiconductor device.

There are various types of semiconductor devices. For example, Japanese Laid-Open Patent Publication No. 2009-105389 discloses an example of a semiconductor device (power module) on which a switching element such as an insulated gate bipolar transistor (IGBT) is mounted.

### BRIEF DESCRIPTION OF DRAWINGS

FIG. 1 is an upper perspective view showing one embodiment of a power semiconductor module.

FIG. 2 is a lower perspective view of the power semiconductor module.

FIG. 3 is a plan view of the power semiconductor module.

FIG. 4 is a side view of the power semiconductor module.

FIG. 5 is a schematic cross-sectional view of the power semiconductor module.

FIG. 6 is a circuit diagram showing one example of the electrical configuration of the power semiconductor module.

FIG. 7 is a perspective view showing the power semiconductor module attached to a heat sink.

FIG. 8 is a diagram illustrating a semiconductor device including the power semiconductor module.

### DETAILED DESCRIPTION

One embodiment of power semiconductor module will now be described with reference to the drawings. The embodiment described below exemplifies configurations and methods for embodying a technical concept without any intention to limit the material, shape, structure, arrangement, dimensions, and the like of each component. Elements in the figures are illustrated for simplicity and clarity and have not necessarily been drawn to scale. To facilitate understanding, hatching lines may not be shown in the cross-sectional drawings. The accompanying drawings illustrate exemplary embodiments in accordance with the present disclosure and are not intended to limit the present disclosure. Terms such as “first”, “second”, and “third” in this disclosure are used to distinguish subjects and not used for ordinal purposes.

### Embodiment

One embodiment of a power semiconductor module 10 will now be described.

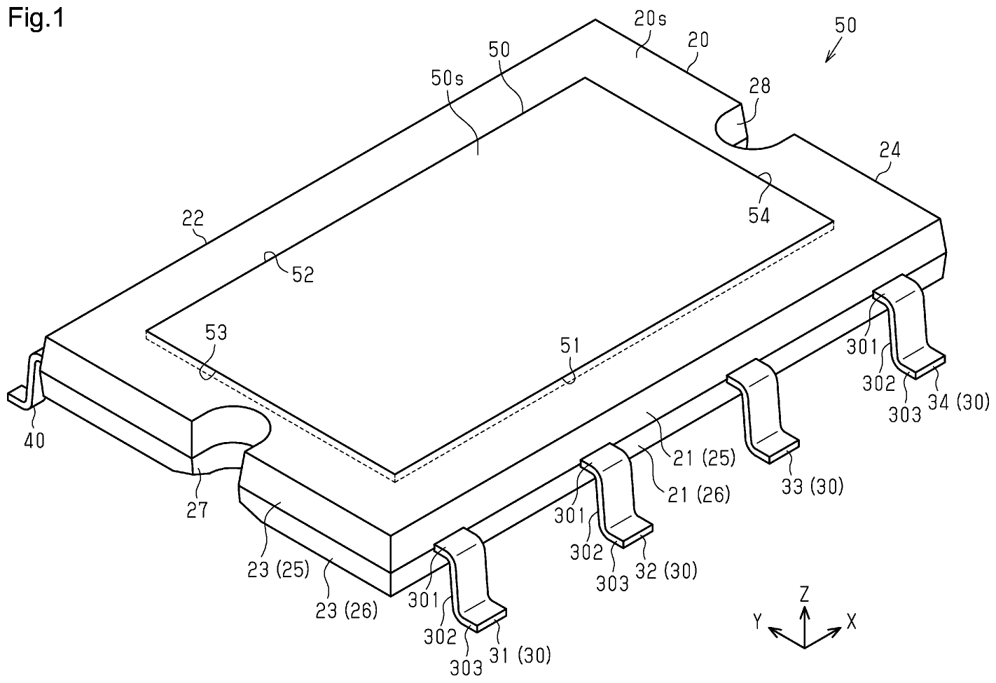

As shown in FIGS. 1 to 4, the power semiconductor module 10 includes a module body 20 and terminals 30 and 40 projecting from the module body 20.

The module body 20 is substantially flat. In the description hereafter, the thickness direction of the module body 20 will be referred to as the Z-direction. The two directions that are orthogonal to the Z-direction and orthogonal to each other are referred to as the X-direction and the Y-direction.

The module body 20 includes a body main surface 20s, a body back surface 20r, and body side surfaces 21, 22, 23, and 24. The body main surface 20s and the body back surface 20r are located at opposite sides in the Z-direction. The body main surface 20s and the body back surface 20r are rectangular as viewed in the Z-direction. In the present embodiment, the body main surface 20s and the body back surface 20r are rectangular and have long sides extending in the X-direction and short sides extending in the Y-direction.

The first body side surface 21 and the second body side surface 22 extend in the X-direction as viewed in the Z-direction. The first body side surface 21 and the second body side surface 22 define the two end surfaces in the Y-direction. The third body side surface 23 and the fourth body side surface 24 extend in the Y-direction as viewed in the Z-direction. The third body side surface 23 and the fourth body side surface 24 define the two end surfaces in the X-direction.

The body side surfaces 21 to 24 each include a first side surface 25 and a second side surface 26. The first side surface 25 is located closer to the body main surface 20s than the body back surface 20r in the Z-direction. The second side surface 26 is located closer to the body back surface 20r than the body main surface 20s in the Z-direction. The first side surface 25 of the first body side surface 21 and the first side surface 25 of the second body side surface 22 are inclined so as to become closer to each other in the Y-direction as they become closer to the body main surface 20s. The first side surface 25 of the third body side surface 23 and the first side surface 25 of the fourth body side surface 24 are inclined so as to become closer to each other in the X-direction as they become closer to the body main surface 20s. The second side surface 26 of the first body side surface 21 and the second side surface 26 of the second body side surface 22 become closer to each other in the Y-direction as they become closer to the body back surface 20r. The second side surface 26 of the third body side surface 23 and the second side surface 26 of the fourth body side surface 24 are inclined toward each other in the X-direction as they become closer to the body back surface 20r. In the present embodiment, the first side surface 25 of each of the body side surfaces 21 to 24 is greater in length in the Z-direction than the second side surface 26 of each of the body side surfaces 21 to 24.

The module body 20 includes pockets 27 and 28. The pocket 27 is included in the third body side surface 23 of the module body 20, and the pocket 28 is included in the fourth body side surface 24. The pocket 27 is located in the middle of the third body side surface 23 in the Y-direction. The pocket 27 is recessed from the third body side surface 23 toward the fourth body side surface 24. The pocket 27 extends through the module body 20 in the Z-direction. The pocket 28 is located in the middle of the fourth body side surface 24 in the Y-direction. The pocket 28 is recessed from the fourth body side surface 24 toward the third body side surface 23. The pocket 28 extends through the module body 20 in the Z-direction.

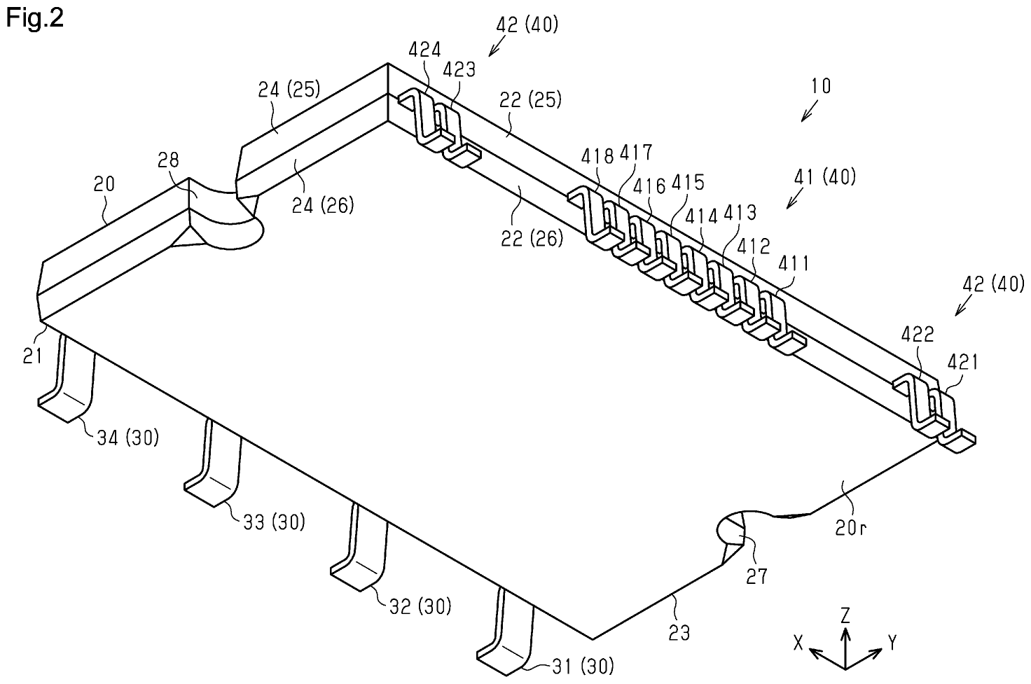

As shown in FIGS. 1, 3, and 5, the first terminals 30 project from the first body side surface 21 of the module body 20. The first terminals 30 project out of the first body side surface 21 from between the first side surface 25 and the second side surface 26. As shown in FIGS. 2 to 5, the second terminals 40 project from the second body side surface 22 of the module body 20. The second terminals 40 project out of the second body side surface 22 from between the first side surface 25 and the second side surface 26. In the module body 20 of the present embodiment, the third body side surface 23 and the fourth body side surface 24 do not include terminals.

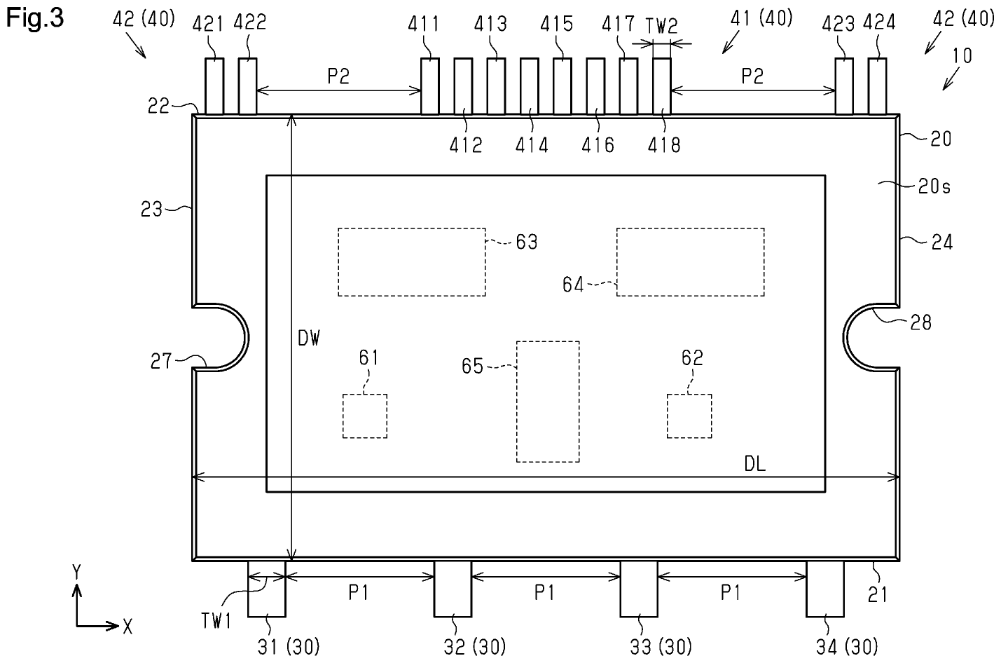

As shown in FIG. 3, the first terminals 30 include four terminals 31, 32, 33, and 34. The terminals 31 to 34 are arranged next to one another on the first body side surface 21 from the third body side surface 23 toward the fourth body side surface 24. The terminals 31 to 34 are spaced apart from one another at predetermined intervals. In the present embodiment, the terminals 31 to 34 are arranged at equal intervals. The terminals 31 to 34 are spaced apart from one another by an interval P1 of, for example, 8 mm.

The first terminals 30 (31 to 34) are identical in shape.

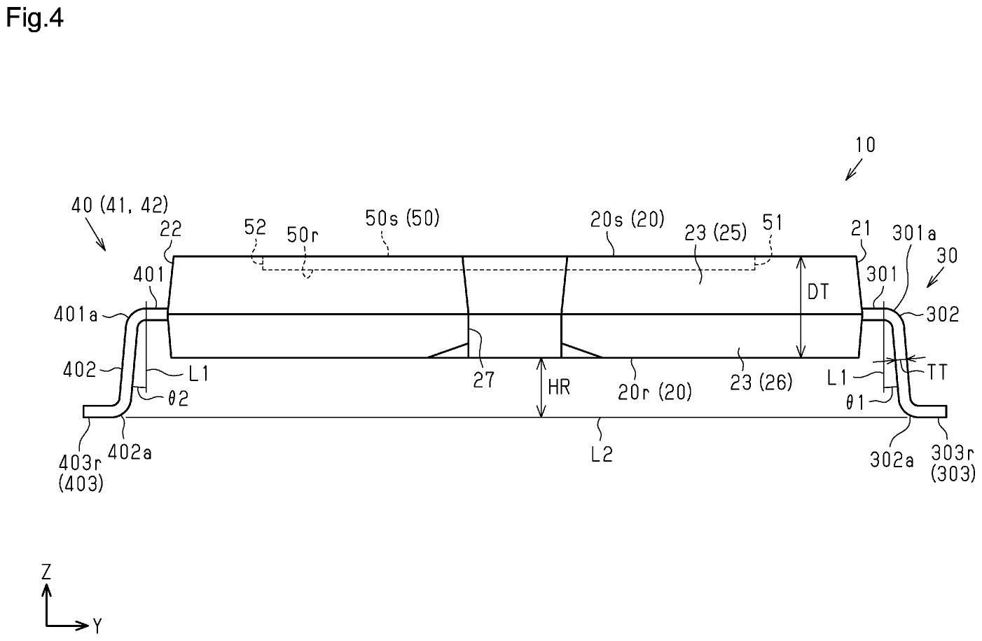

As shown in FIG. 4, the first terminals 30 each include a first portion 301, a second portion 302, and a third portion 303. The first portion 301 extends in the direction of projection from the first body side surface 21, that is, the Y-direction. The second portion 302 extends from a distal end 301a of the first portion 301 toward the side of the body back surface 20r opposite the body main surface 20s. The third portion 303 extends from a distal end 302a of the second portion 302 in the direction of projection from the first body side surface 21, that is, the Y-direction. Thus, the third portion 303 of the first terminal 30 is located at the side of the body back surface 20r of the module body 20 opposite the body main surface 20s. The first portion 301 and the third portion 303 extend away from the first body side surface 21. The second portion 302 is inclined from the first portion 301 so that the first body side surface 21 becomes farther as the third portion 303 becomes closer.

As shown in FIGS. 2 to 5, the second terminals 40 include primary terminals 41 and secondary terminals 42. In the present embodiment, the primary terminals 41 include eight primary terminals 411 to 418. The secondary terminals 42 include four secondary terminals 421 to 424.

As shown in FIG. 3, the primary terminals 411 to 418 are located at the middle of the second body side surface 22 in the X-direction. The secondary terminals 421 to 424 are located at opposite sides of the primary terminals 41 (411 to 418). The primary terminals 411 to 418 are arranged next to one another on the second body side surface 22 from the third body side surface 23 toward the fourth body side surface 24. The secondary terminals 421 and 422 are located toward the third body side surface 23 from the primary terminals 41 (411 to 418). The secondary terminals 423 and 424 are located toward the fourth body side surface 24 from the primary terminals 41 (411 to 418). The primary terminals 41 are spaced apart from the secondary terminals 42 by an interval P2 of, for example, 8 mm.

The second terminals 40 (411 to 414 and 421 to 424) are identical in shape.

As shown in FIG. 4, the second terminals 40 each include a first portion 401, a second portion 402, and a third portion 403. The first portion 401 extends in the direction of projection from the second body side surface 22, that is, the Y-direction. The second portion 402 extends from a distal end 401a of the first portion 401 toward the side of the body back surface 20r opposite the body main surface 20s. The third portion 403 extends from a distal end 402a of the second portion 402 in the direction of projection from the first body side surface 21, that is, the Y-direction. Thus, the third portion 403 of the first terminal 30 is located at the side of the body back surface 20r of the module body 20 opposite the body main surface 20s. The first portion 401 and the third portion 403 extend away from the second body side surface 22. The second portion 402 is inclined from the first portion 401 so that the second body side surface 22 becomes farther as the third portion 403 becomes closer.

The first terminals 30 and the second terminals 40 each include a base and a plating layer. The base is formed from an electrically conductive metal. For example, the base is formed from copper (Cu) or an alloy containing Cu. The plating layer covers the surface of the base. The plating layer is formed from an electrically conductive metal. The metal forming the plating layer includes, for example, solder. In the first terminals 30 and the second terminals 40, the base may be exposed or covered by the plating layer at the end surfaces of the third portions 303 and 403.

As shown in FIG. 3, the module body 20 has a length DL in the X-direction of 30 mm to 70 mm, inclusive. In the present embodiment, the length DL of the module body 20 in the X-direction is 38 mm. The module body 20 has a width DW in the Y-direction of 20 mm to 40 mm, inclusive. In the present embodiment, the width DW of the module body 20 in the Y-direction is 24 mm. As shown in FIG. 4, the module body 20 has a thickness DT in the Z-direction of 2 mm to 7 mm, inclusive. In the present embodiment, the thickness DT of the module body 20 in the Z-direction is 3.5 mm.

As shown in FIG. 4, the terminals 30 and 40 have a thickness TT of 0.35 mm to 1.0 mm, inclusive. In the present embodiment, the thickness T of the terminals 30 and 40 is 0.6 mm.

As shown in FIG. 3, the first terminals 30 have a width TW1, which is the dimension in the X-direction, of, for example, 2 mm. The second terminals 40 have a width TW2 of, for example, 1 mm.

As shown in FIG. 4, in each first terminal 30, the inclination angle of the second portion 302 is, for example, the angle of the second portion 302 with respect to a line segment L1 that is orthogonal to the first portion 301. The inclination angle θ1 of the second portion 302 is 0 degrees to 5 degrees, inclusive. In the same manner as the first terminal 30, the inclination angle θ2 of the second portion 402 in each second terminal 40 is 0 degrees to 5 degrees, inclusive.

As shown in FIG. 4, the first terminals 30 and the second terminals 40 respectively include the third portions 303 and 403 that are located below the body back surface 20r of the module body 20 at the side of the body back surface 20r opposite the body main surface 20s. The third portions 303 and 403 respectively include mounting surfaces 303r and 403r facing the same direction as the body back surface 20r.

In the present embodiment, as viewed in the X-direction, the body back surface 20r of the module body 20 is spaced apart from a line segment L2 connecting the lower ends of the first terminals 30 and the second terminals 40. The line segment L2, for example, extends along a plane where the lower ends of the first terminals 30 and the second terminals 40 are located as viewed in the Z-direction. The distance from the line segment L2 to the body back surface 20r is referred to as the back surface height HR. In other words, the back surface height HR is the height of the body back surface 20r in the Z-direction from the lower ends of the first terminals 30 and the second terminals 40. The height of the first terminals 30 and the second terminals 40 is set so that the back surface height HR is within a predetermined range. The back surface height HR is 1.5 mm to 3.0 mm, inclusive. In the present embodiment, the back surface height HR is 2.0 mm.

The first terminals 30 and the second terminals 40 are for mounting the power semiconductor module 10 on a circuit board used with the power semiconductor module 10. The first terminals 30 and the second terminals 40 are mounted with the mounting surfaces 303r and 403r of the third portions 303 and 403 facing the circuit board.

As shown in FIG. 3, the module body 20 includes a heat dissipating member 50. The heat dissipating member 50 is arranged on the body main surface 20s of the module body 20.

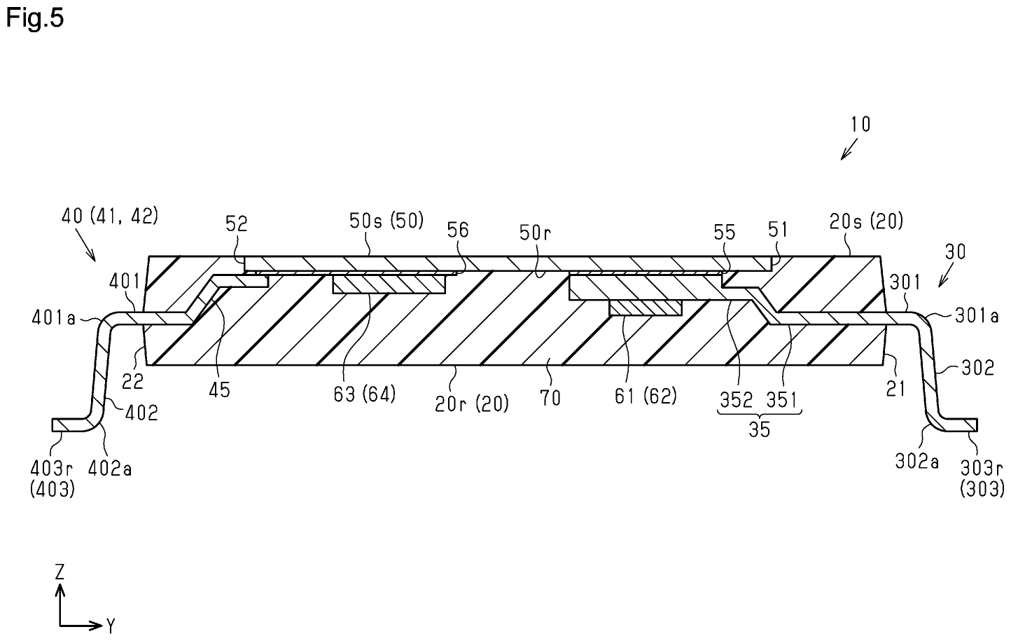

The heat dissipating member 50 includes a main surface 50s, a back surface 50r, and side surfaces 51, 52, 53, and 54. The main surface 50s, the back surface 50r, and the side surfaces 51, 52, 53, and 54 respectively face the same directions as the body main surface 20s, the body back surface 20r, and the body side surfaces 21, 22, 23, and 24. As shown in FIGS. 4 and 5, in the present embodiment, the main surface 50s of the heat dissipating member 50 is flush with the body main surface 20s of the module body 20. As shown in FIGS. 1 and 3, the main surface 50s of the heat dissipating member 50 is exposed from the body main surface 20s of the module body 20. As long as the main surface 50s of the heat dissipating member 50 is exposed from the body main surface 20s, the main surface 50s of the heat dissipating member 50 does not have to be flush with the body main surface 20s. For example, the heat dissipating member 50 can project outward from the body main surface 20s in the Z-direction. Alternatively, the main surface 50s of the heat dissipating member 50 can be located toward the body back surface 20r from the body main surface 20s.

The heat dissipating member 50 is formed from a thermally conductive material. Preferably, the heat dissipating member 50 is insulative. The heat dissipating member 50 is formed from, for example, a ceramic. The ceramic contains, for example, alumina (Al₂O₃) as a main component.

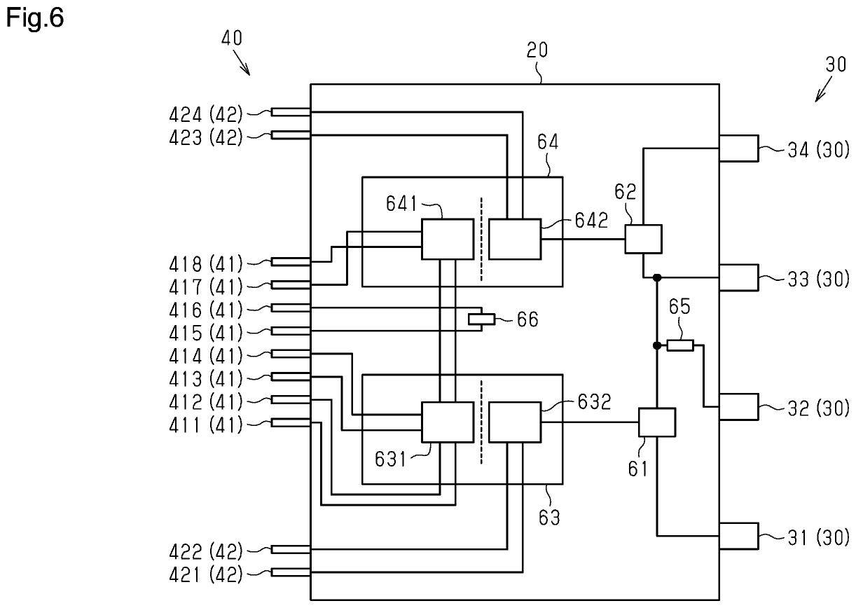

As shown in FIGS. 3 and 5, the module body 20 includes power semiconductor elements 61 and 62 and drive circuits 63 and 64. The module body 20 of the present embodiment includes a resistance element 65. Further, the module body 20 of the present embodiment includes a temperature detection resistor 66 that is shown in FIG. 6. Electric members other than the power semiconductor elements 61 and 62, the drive circuits 63 and 64, the resistance element 65, and the temperature detection resistor 66 may also be included.

As shown in FIG. 5, the module body 20 includes an encapsulation resin 70 that covers the power semiconductor element 61 (62) and the drive circuit 63 (64). Although not shown in the drawings, the encapsulation resin 70 also covers the resistance element 65 and the temperature detection resistor 66 that are shown in FIG. 6. The encapsulation resin 70 is formed from an insulative material. One example of the insulative material is an epoxy resin. In the present embodiment, the module body 20 is formed from a black epoxy resin. The surface of the encapsulation resin 70 defines the surface of the module body 20. The encapsulation resin 70 includes a resin main surface, a resin back surface, and resin side surfaces.

As shown in FIG. 5, the module body 20 includes first internal terminals 35 and second internal terminals 45. The first internal terminals 35 are respectively connected to the first terminals 30. The first internal terminals 35 are formed integrally with the corresponding first terminals 30. For example, the first internal terminals 35 serve as inner leads, and the first terminals 30 serve as outer leads. Each first internal terminal 35 is formed by the base of the corresponding first terminal 30.

Each first internal terminal 35 includes an internal lead 351 and a die pad 352. The internal lead 351 connects the die pad 352 to the corresponding first terminal 30. The terminals 31 to 34, which are shown in FIG. 3, each include the internal lead 351 and the die pad 352. The die pad 352 is connected by a bonding member (not shown) to a bonding portion 55 formed on the back surface 50r of the heat dissipating member 50. The bonding portion 55 is formed by, for example, sintering a metal material such as a silver (Ag) paste or a Cu paste. The bonding member is solder, an Ag paste, or the like. For example, the power semiconductor element 61 is mounted on the die pad 352 of the terminal 33, and the power semiconductor element 62 is mounted on the die pad 352 of the terminal 34. The resistance element 65 shown in FIG. 3 is, for example, connected between the die pad 352 of the terminal 32 and the die pad 352 of the terminal 33. The power semiconductor elements 61 and 62 are each connected by a bonding member such as an Ag paste to the corresponding die pad 352.

The second internal terminals 45 are respectively connected to the second terminals 40. The second internal terminals 45 are formed integrally with the second terminals 40. For example, the second internal terminals 45 serve as inner leads, and the second terminals 40 serve as outer leads. Each second internal terminal 45 is formed by the base of the corresponding second terminal 40.

The second internal terminals 45 are connected to a wiring pattern 56 formed on the back surface 50r of the heat dissipating member 50. The wiring pattern 56 is formed by, for example, sintering a metal material such as an Ag paste or a Cu paste. The bonding member is solder, an Ag paste, or the like. The wiring pattern 56 is connected to the drive circuits 63 and 64 and the temperature detection resistor 66, which are shown in FIG. 6. Each of the drive circuits 63 and 64 is, for example, a surface-mounted semiconductor package such as a thin small outline package (TSOP). The wiring pattern 56 is connected by wires (not shown) to the power semiconductor elements 61 and 62. Semiconductor chips may be used as the drive circuits 63 and 64. The semiconductor chips are directly connected to the wiring pattern 56 of the heat dissipating member 50 or mounted on die pads and connected by wires to the wiring pattern and the power semiconductor elements 61 and 62.

FIG. 6 shows the circuit configuration of the power semiconductor module 10.

The power semiconductor module 10 includes the first power semiconductor element 61, the second power semiconductor element 62, the first drive circuit 63, the second drive circuit 64, the resistance element 65, and the temperature detection resistor 66.

Each of the first power semiconductor element 61 and the second power semiconductor element 62 is, for example, a metal-oxide-semiconductor field-effect transistor using a silicon carbide (SiC) substrate (SiC MOSFET). In the present embodiment, each of the power semiconductor elements 61 and 62 is an N-type MOSFET. The power semiconductor elements 61 and 62 may each be a MOSFET using a silicon (Si) substrate and include, for example, an insulated gate bipolar transistor (IGBT) element.

The first power semiconductor element 61 includes a gate terminal connected to the first drive circuit 63, a drain terminal connected to the terminal 33, and a source terminal connected to the terminal 30. The second power semiconductor element 62 includes a gate terminal connected to the second drive circuit 64, a drain terminal connected to the terminal 34, and a source terminal connected to the terminal 33. The source terminal of the first power semiconductor element 61 is connected to the drain terminal of the second power semiconductor element 62. Thus, the first power semiconductor element 61 and the second power semiconductor element 62 are connected in series between the terminals 31 and 34 of the first terminals 30. A connection node between the first power semiconductor element 61 and the second power semiconductor element 62 is connected to a first terminal of the resistance element 65. A second terminal of the resistance element 65 is connected to the terminal 32.

The first drive circuit 63 includes a primary circuit 631 and a secondary circuit 632. The primary circuit 631 is insulated from the secondary circuit 632 by, for example, a transformer, a capacitor, or the like. A transformer and a capacitor allow for the transmission of a signal when magnetic coupling occurs. Thus, the primary circuit 631 and the secondary circuit 632 are configured to be DC insulated while allowing for signal transmission.

The second drive circuit 64 includes a primary circuit 641 and a secondary circuit 642. The primary circuit 641 is insulated from the secondary circuit 642 by, for example, a transformer, a capacitor, or the like. A transformer and a capacitor allow for the transmission of a signal when magnetic coupling occurs. Thus, the primary circuit 641 and the secondary circuit 642 are configured to be DC insulated while allowing for signal transmission.

The second terminals 40 are connected to the first drive circuit 63 and the second drive circuit 64.

The primary terminals 411 to 418 of the second terminals 40 are connected to the primary circuits 631 and 641. The primary terminals 411 and 412 supply a first voltage to the primary circuits 631 and 641. The primary circuits 631 and 641 are configured to be activated when supplied with the first voltage. The primary terminals 413 and 414 provide a control signal to the primary circuit 631 of the first drive circuit 63. The primary circuit 631 generates a signal based on the provided control signal and transmits the generated signal to the secondary circuit 632. The primary terminals 415 and 416 are connected to the temperature detection resistor 66. The temperature detection resistor 66 detects the temperature of the module body 20. The primary terminals 417 and 418 provide a control signal to the primary circuit 641 of the second drive circuit 64. The primary circuit 641 generates a signal based on the provided control signal and transmits the generated signal to the secondary circuit 642.

The secondary terminals 421 and 422 are connected to the secondary circuit 632 of the first drive circuit 63. The secondary terminals 421 and 422 supply a second voltage to the secondary circuit 632. The second voltage is greater than the first voltage supplied to, for example, the primary circuit. The secondary circuit 632 is configured to be activated when supplied with the second voltage. In response to a signal received from the primary circuit 631, the secondary circuit 632 generates a drive signal for driving the first power semiconductor element 61 and provides the drive signal to the first power semiconductor element 61.

The secondary terminals 423 and 424 are connected to the secondary circuit 642 of the second drive circuit 64. The secondary terminals 423 and 424 supply a second voltage to the secondary circuit 642. The second voltage is greater than the first voltage supplied to, for example, the primary circuit. The secondary circuit 642 is configured to be activated when supplied with the second voltage. In response to a signal received from the primary circuit 641, the secondary circuit 642 generates a drive signal for driving the second power semiconductor element 62 and provides the drive signal to the second power semiconductor element 62.

### Operation

The operation of the power semiconductor module 10 will now be described.

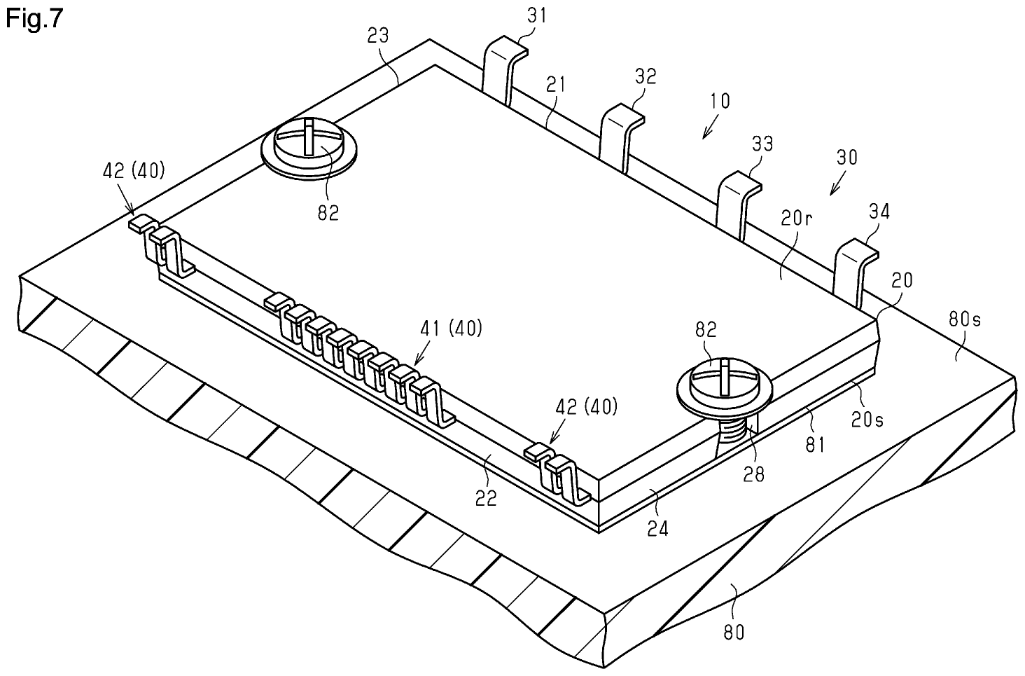

As shown in FIG. 7, a heat dissipator 80 is attached to the power semiconductor module 10 of the present embodiment. The heat dissipator 80 has, for example, the form of a flat plate. The heat dissipator 80 includes a heat dissipator main surface 80s facing the Z-direction. The heat dissipator main surface 80s is, for example, flat. The heat dissipator 80 is formed from, for example, a thermally conductive material such as aluminum.

A sheet member 81 is arranged between the power semiconductor module 10 and the heat dissipator 80. The sheet member 81 is sandwiched between the body main surface 20s of the module body 20 of the power semiconductor module 10 and the heat dissipator main surface 80s of the heat dissipator 80. The heat dissipating member 50 is exposed from the body main surface 20s of the module body 20. Thus, the sheet member 81 is sandwiched between the main surface 50s of the heat dissipating member 50 and the heat dissipator main surface 80s of the heat dissipator 80. The sheet member 81 fills a gap extending from the body main surface 20s and the main surface 50s to the heat dissipator main surface 80s. The sheet member 81 is rectangular as viewed in the Z-direction. In the present embodiment, the sheet member 81 is sized and shaped in conformance with the module body 20.

The sheet member 81 is formed from a thermally conductive material. Preferably, the sheet member 81 is formed from an insulative material. The sheet member 81 is formed from, for example, a silicone resin.

As shown in FIG. 7, the heat dissipator 80 is fixed by bolts 82 to the power semiconductor module 10. The bolts 82 are fitted into the pockets 27 and 28 in the module body 20 of the power semiconductor module 10. The bolts 82 are fastened to threaded holes (not shown) of the heat dissipator 80. The bolts 82 are examples of fasteners that fasten the heat dissipator 80 to the power semiconductor module 10.

The attachment of the heat dissipator 80 to the power semiconductor module 10 allows the heat generated by the power semiconductor elements 61 and 62, which are shown in FIG. 4, to be dissipated out of the power semiconductor module 10 efficiently with the heat dissipating member 50 and the heat dissipator 80, which is shown in FIG. 7. Further, the arrangement of the sheet member 81 between the module body 20 and the heat dissipator 80 allows heat to be transferred efficiently from the power semiconductor elements 61 and 62 to the heat dissipator 80.

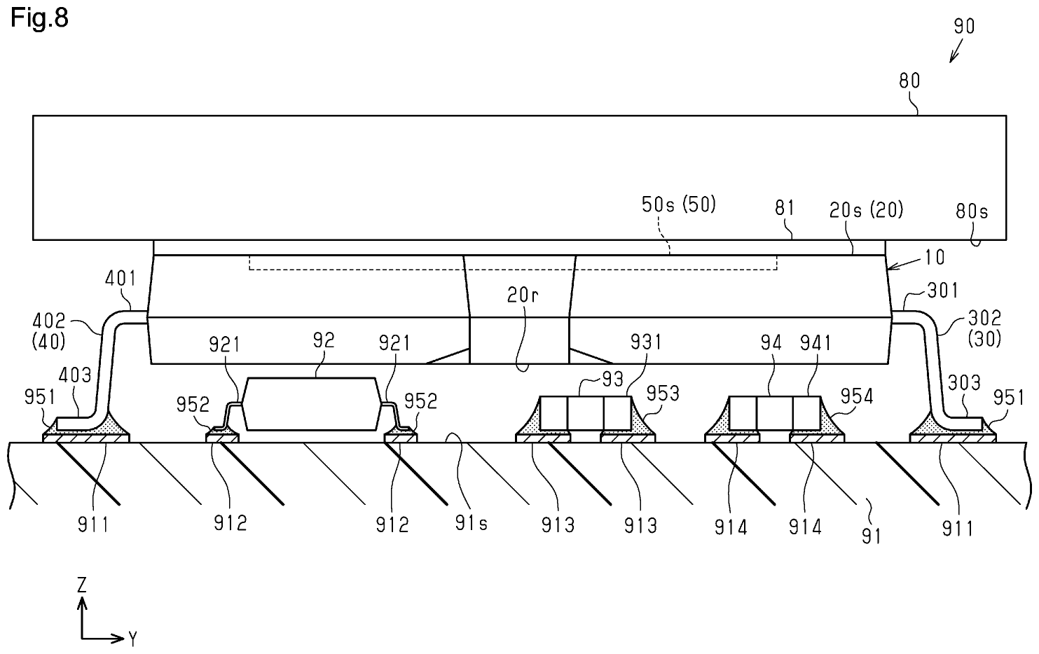

FIG. 8 shows part of a semiconductor device 90 including the power semiconductor module 10 of the present embodiment. The semiconductor device 90 includes the power semiconductor module 10, a circuit board 91, and electronic components 92, 93, and 94. The circuit board 91 includes a board main surface 91s. Pads 911, 912, 913, and 914 are arranged on the board main surface 91s. The first terminals 30 and the second terminals 40 of the power semiconductor module 10 are connected by solder 951 to the pads 911. The module body 20 of the power semiconductor module 10 overlaps the electronic components 92, 93, and 94 in the Z-direction.

The electronic component 92 is, for example, an LSI such as an ECU. The electronic component 92 includes terminals 921 connected by solder 952 to the pads 912. The electronic components 93 and 94 include electrodes 931 and 941 connected by solder 953 and 954 to the pads 913 and 914. The electronic component 92 is an LSI that includes a control circuit for controlling the power semiconductor module 10 and is connected to the primary terminals 41 shown in FIG. 6. A circuit pattern (not shown) is formed on the circuit board 91 to connect the power semiconductor module 10 and the electronic component 92. The electronic components 93 and 94 are, for example, resistance elements, capacitors, transistors, diodes, or the like.

The power semiconductor module 10 of the present embodiment includes the first terminals 30, which project from the first body side surface 21, and the second terminals 40, which project from the second body side surface 22.

The first terminals 30 each include the first portion 301, the second portion 302, and the third portion 303. The first portion 301 extends in the direction of projection from the first body side surface 21, that is, the Y-direction. The second portion 302 extends from the distal end 301a of the first portion 301 toward the side of the body back surface 20r opposite the body main surface 20s. The third portion 303 extends from the distal end 302a of the second portion 302 in the direction of projection from the first body side surface 21, that is, the Y-direction. Thus, the third portion 303 of the first terminal 30 is located at the side of the body back surface 20r of the module body 20 opposite the body main surface 20s.

The second terminals 40 each include the first portion 401, the second portion 402, and the third portion 403. The first portion 401 extends in the direction of projection from the second body side surface 22, that is, the Y-direction. The second portion 402 extends from the distal end 401a of the first portion 401 toward the side of the body back surface 20r opposite the body main surface 20s. The third portion 403 extends from a distal end 402a of the second portion 402 in the direction of projection from the first body side surface 21, that is, the Y-direction. Thus, the third portion 403 of the first terminal 30 is located at the side of the body back surface 20r of the module body 20 opposite the body main surface 20s.

As shown in FIG. 8, the power semiconductor module 10 of the present embodiment may be mounted with the solder 951 on the pads 911 arranged on the board main surface 91s of the circuit board 91. This facilitates mounting as compared with when terminals are inserted into through holes of a circuit board. Further, the first terminals 30 and the second terminals 40 only need to be positioned on the pads 911 of the circuit board 91. Thus, a mounting device can be used to perform the mounting.

In the power semiconductor module 10 of the present embodiment, as viewed in the X-direction, the module body 20 is arranged so that the body back surface 20r of the module body 20 is spaced apart from the line segment L2 connecting the lower ends of the first terminals 30 and the second terminals 40. This allows the power semiconductor module 10 to be mounted on the circuit board 91 with the module body 20 of the power semiconductor module 10 overlapping the electronic components 92, 93, and 94, which are mounted on the circuit board 91. Thus, the mounting area of the semiconductor device 90 can be decreased, and the size of the semiconductor device 90 can be reduced.

The second portion 302 of each first terminal 30 is inclined from the corresponding first portion 301 so that the first body side surface 21 becomes farther toward the body back surface 20r. In the same manner, the second portion 402 of each second terminal 40 is inclined from the corresponding first portion 401 so that the second body side surface 22 becomes farther toward the body back surface 20r.

This structure reduces the external force applied to the power semiconductor module 10 and mitigates the stress caused by temperature-related expansion and contraction differences between the power semiconductor module 10 and the circuit board 91. Further, the module body 20 is arranged so that the body back surface 20r of the module body 20 is separated by the length of the first terminals 30 and the second terminals 40 from the board main surface 91s of the circuit board 91, where the first terminals 30 and the second terminals 40 are mounted. This allows the power semiconductor module 10 of the present embodiment to further mitigate stress as compared with a structure in which the body back surface 20r is in contact with the board main surface 91s.

As shown in FIGS. 3 and 6, the first terminals 30, which are connected to the power semiconductor elements 61 and 62, are greater in width than the second terminals 40, which are connected to the drive circuits 63 and 64. Further, in each first terminal 30, the first portion 301, the second portion 302, and the third portion 303 have the same width. This allows for the flow of a large current when the power semiconductor elements 61 and 62 are driven.

The second terminals 40 include the primary terminals 41 (411 to 418), which are connected to the primary circuits 631 and 641 of the drive circuits 63 and 64, and the secondary terminals 42 (421 to 424), which are connected to the secondary circuits 632 and 642. The secondary terminals 421 and 422 and the secondary terminals 423 and 424 are located at opposite sides of the primary terminals 411 to 418. The secondary terminals 421 to 424 supply the secondary circuits 632 and 642 with the second voltage that is higher than the first voltage supplied to activate the primary circuits 631 and 641. Further, the secondary terminals 421 to 424 are separated from the primary terminals 411 to 418. This ensures insulation (creepage distance) between the primary terminals 411 to 418 and the secondary terminals 421 to 424.

### Advantages

As described above, the present embodiment has the following advantages.

(1) The power semiconductor module 10 of the present embodiment includes the first terminals 30, which project from the first body side surface 21, and the second terminals 40, which project from the second body side surface 22. The first terminals 30 each include the first portion 301, the second portion 302, and the third portion 303. The first portion 301 extends in the direction of projection from the first body side surface 21, that is, the Y-direction. The second portion 302 extends from the distal end 301a of the first portion 301 toward the side of the body back surface 20r opposite the body main surface 20s. The third portion 303 extends from the distal end 302a of the second portion 302 in the direction of projection from the first body side surface 21, that is, the Y-direction. Thus, the third portion 303 of the first terminal 30 is located at the side of the body back surface 20r of the module body 20 opposite the body main surface 20s. The second terminals 40 each include the first portion 401, the second portion 402, and the third portion 403. The first portion 401 extends in the direction of projection from the second body side surface 22, that is, the Y-direction. The second portion 402 extends from the distal end 401a of the first portion 401 toward the side of the body back surface 20r opposite the body main surface 20s. The third portion 403 extends from the distal end 402a of the second portion 402 in the direction of projection from the first body side surface 21, that is, the Y-direction. Thus, the third portion 403 of the first terminal 30 is located at the side of the body back surface 20r of the module body 20 opposite the body main surface 20s.

The power semiconductor module 10 of the present embodiment is mounted on the pads 911 arranged on the board main surface 91s of the circuit board 91 with solder 951. This facilitates mounting as compared with when terminals are inserted into through holes of a circuit board. Further, the first terminals 30 and the second terminals 40 only need to be positioned on the pads 911 of the circuit board 91. Thus, a mounting device can be used to perform the mounting.

(2) In the power semiconductor module 10 of the present embodiment, as viewed in the X-direction, the module body 20 is arranged so that the body back surface 20r of the module body 20 is spaced apart from the line segment L2 connecting the lower ends of the first terminals 30 and the second terminals 40. This allows the power semiconductor module 10 to be mounted on the circuit board 91 with the module body 20 of the power semiconductor module 10 overlapping the electronic components 92, 93, and 94, which are mounted on the circuit board 91. Thus, the mounting area of the semiconductor device 90 can be decreased, and the size of the semiconductor device 90 can be reduced.

(3) The second portion 302 of each first terminal 30 is inclined from the corresponding first portion 301 so that the first body side surface 21 becomes farther toward the body back surface 20r. In the same manner, the second portion 402 of each second terminal 40 is inclined from the corresponding first portion 401 so that the second body side surface 22 becomes farther toward the body back surface 20r. This structure reduces the external force applied to the power semiconductor module 10 and mitigates the stress caused by temperature-related expansion and contraction differences between the power semiconductor module 10 and the circuit board 91. Further, the module body 20 is arranged so that the body back surface 20r of the module body 20 is separated by the length of the first terminals 30 and the second terminals 40 from the board main surface 91s of the circuit board 91, where the first terminals 30 and the second terminals 40 are mounted. This allows the power semiconductor module 10 of the present embodiment to further mitigate stress as compared with a structure in which the body back surface 20r is in contact with the board main surface 91s.

(4) The first terminals 30, which are connected to the power semiconductor elements 61 and 62, are greater in width than the second terminals 40, which are connected to the drive circuits 63 and 64. Further, in each first terminal 30, the first portion 301, the second portion 302, and the third portion 303 have the same width. This allows for the flow of a large current when the power semiconductor elements 61 and 62 are driven.

(5) The second terminals 40 include the primary terminals 41 (411 to 418), which are connected to the primary circuits 631 and 641 of the drive circuits 63 and 64, and the secondary terminals 42 (421 to 424), which are connected to the secondary circuits 632 and 642. The secondary terminals 421 and 422 and the secondary terminals 423 and 424 are located at opposite sides of the primary terminals 411 to 418. The secondary terminals 421 to 424 supply the secondary circuits 632 and 642 with the second voltage that is higher than the first voltage supplied to activate the primary circuits 631 and 641. Further, the secondary terminals 421 to 424 are separated from the primary terminals 411 to 418. This ensures insulation (creepage distance) between the primary terminals 411 to 418 and the secondary terminals 421 to 424.

(6) The power semiconductor module 10 of the present embodiment is attached to the heat dissipator 80. Thus, the heat generated by the power semiconductor elements 61 and 62 is dissipated efficiently by the heat dissipating member 50 and the heat dissipator 80. Further, the arrangement of the sheet member 81 between the module body 20 and the heat dissipator 80 allows heat to be transferred efficiently from the power semiconductor elements 61 and 62 to the heat dissipator 80.

### Modified Examples

The embodiments described above exemplify, without any intention to limit, applicable forms of an insulation module according to this disclosure. The insulation module in accordance with this disclosure may be modified from the embodiments described above. For example, the configuration in the above embodiment may be replaced, changed, or omitted in part or include an additional element. The modified examples described below may be combined as long as there is technical consistency. In the modified examples described hereafter, same reference characters are given to those components that are the same as the corresponding components of the above embodiments. Such components will not be described in detail.

In the above embodiment, a metal board may be used as the heat dissipating member 50. The metal board is formed from Cu, a Cu alloy, Al, an Al alloy, or the like. The heat dissipating member 50 includes an insulation layer formed on the metal board and a wiring pattern formed on the insulation layer.

In the above embodiment, the resistance element 65 shown in FIGS. 3 and 6 may be omitted. In this case, the terminal 32 (first terminal 30) shown in FIG. 4 may include the first portion 301 to the third portion 303 (refer to FIG. 4) or include only the first portion 301 and have the second portion 302 and the third portion 303 omitted.

In the above embodiment, the temperature detection resistor 66 shown in FIG. 6 may be omitted. In this case, the primary terminals 415 and 416 (second terminals 40) may each include the first portion 401 to the third portion 403 (refer to FIG. 4) or include only the first portion 401 and have the second portion 402 and the third portion 403 omitted.

In the above embodiment, the second power semiconductor element 62 may be connected in parallel to the first power semiconductor element 61.

In the above embodiment, the second power semiconductor element 62 may be connected to a terminal that is not connected to the first power semiconductor element. For example, in the circuit illustrated in FIG. 6, the resistance element 65 may be omitted, and the drain terminal of the first power semiconductor element 61 may be connected to only the terminal 32 (first terminal 3).

The above embodiment may include a dummy terminal that supports the module body 20.

In this specification, the word “on” includes the meaning of “above” in addition to the meaning of “on” unless otherwise described in the context. Accordingly, the phrase of “A formed on B” means that A contacts B and is directly arranged on B, and may also mean, as a modified example, that A is arranged above B without contacting B. Thus, the word “on” will also allow for a structure in which another member is formed between A and B.

### Clauses

Technical concepts that can be understood from each of the above embodiments and modified examples will now be described. Reference characters used in the described embodiment are added to corresponding elements in the clauses to aid understanding without any intention to impose limitations to these elements. The reference characters are given as examples to aid understanding and not intended to limit elements to the elements denoted by the reference characters.

### [Clause 1]

A power semiconductor module, including:
a module body (20) including a body main surface (20s), a body back surface (20r), a first body side surface (21), and a second body side surface (22), the body main surface (20s) facing a thickness direction and including a power semiconductor element (61, 62) and a drive circuit (63, 64), the body back surface (20r) facing a direction opposite the body main surface (20s), the first body side surface (21) facing a direction intersecting the thickness direction, and the second body side surface (22) facing a direction opposite the first body side surface (21);
first terminals (30) projecting from the first body side surface (21); and
second terminals (40) projecting from the second body side surface (22);
the first terminals (30) each including a first portion (301) extending from the first body side surface (21), a second portion (302) extending downward from the first portion (301) to below the body back surface (20r), and a third portion (303) extending from a lower end of the second portion (302) and located below the body back surface (20r); and
the second terminals (40) each including a first portion (401) extending from the second body side surface (22), a second portion (402) extending downward from the first portion (401) to below the body back surface (20r), and a third portion (403) extending from a lower end of the second portion (402) and located below the body back surface (20r).

### [Clause 2]

The power semiconductor module according to clause 1, where the module body (20) includes a heat dissipating member (50) on the body main surface (20s).

### [Clause 3]

The power semiconductor module according to clause 2, where: the heat dissipating member (50) includes a heat dissipating main surface (50s) facing the same direction as the body main surface (20s); and
the heat dissipating main surface (50s) is flush with the body main surface (20s).

### [Clause 4]

The power semiconductor module according to any one of clauses 1 to 3, where:
the second portion (302) of each of the first terminals (30) is inclined from the first portion (301) so that the first body side surface (21) becomes farther as the third portion (303) becomes closer; and
the second portion (402) of each of the second terminals (40) is inclined from the first portion (401) so that the second body side surface (22) becomes farther as the third portion (403) becomes closer.

### [Clause 5]

The power semiconductor module according to any one of clauses 1 to 4, where the second portion (302, 402) is longer than the first portion (301, 401).

### [Clause 6]

The power semiconductor module according to any one of clauses 1 to 5, where a length of the second portion (302, 402) is greater than a thickness of module body (20).

### [Clause 7]

The power semiconductor module according to any one of clauses 1 to 6, where the first terminals (30) include terminals that are wider than the second terminals (40).

### [Clause 8]

The power semiconductor module according to any one of clauses 1 to 7, where: the first terminals (30) are connected to the power semiconductor element (61, 62); and the second terminals (40) are connected to the drive circuit (63, 64).

### [Clause 9]

The power semiconductor module according to clause 8, where:
the drive circuit (63, 64) includes
   a primary circuit (631, 641) provided with a control signal for the power semiconductor element (61, 62), and
   a secondary circuit (632, 642) insulated from the primary circuit (631, 641) and configured to receive a signal from the primary circuit (631, 641), the secondary circuit (632, 642) being connected to the power semiconductor element (61, 62); and
the second terminals (40) include
   primary circuit terminals (41) that are connected to the primary circuit (631, 641), and
   secondary circuit terminals (42) that are connected to the secondary circuit (632, 642).

### [Clause 10]

The power semiconductor module according to clause 9, where:
the primary circuit terminals (41) are arranged at equal intervals; and
an interval between the secondary circuit terminals (42) and the primary circuit terminals (41) is greater than the interval between the primary circuit terminals (41).

### [Clause 11]

The power semiconductor module according to clause 10, where the secondary circuit terminals (42) are arranged at equal intervals, and the interval between the secondary circuit terminals (42) is equal to the intervals between the primary circuit terminals (41).

### [Clause 12]

The power semiconductor module according to any one of clauses 9 to 11, where: the power semiconductor element (61, 62) includes a first power semiconductor element (61) and a second power semiconductor element (62);
the drive circuit (63, 64) includes a first drive circuit (63) that is connected to the first power semiconductor element (61) and a second drive circuit (64) that is connected to the second power semiconductor element (62);
the secondary circuit terminals (42) include a first one of the secondary circuit terminals (421, 422) that is connected to the secondary circuit (632) of the first drive circuit (63) and a second one of the secondary circuit terminals (423, 424) that is connected to the secondary circuit (642) of the second drive circuit (64); and
the first one of the secondary circuit terminals (421, 422) and the second one of the secondary circuit terminals (423, 424) are arranged sandwiching the primary circuit terminals (41, 411-418).

### [Clause 13]

The power semiconductor module according to clause 12, where the first power semiconductor element (61) and the second power semiconductor element (62) are connected in series.

### [Clause 14]

The power semiconductor module according to any one of clauses 1 to 13, where the power semiconductor element (61, 62) is a SiC MOSFET.

### [Clause 15]

The power semiconductor module according to any one of clauses 1 to 13, where the power semiconductor element (61, 62) is an IGBT.

### [Clause 16]

The power semiconductor module according to any one of clauses 1 to 15, where the first terminals (30) and the second terminals (40) each have a thickness of 0.35 mm to 1.0 mm, inclusive.

### [Clause 17]

A semiconductor device, including:
the power semiconductor module (10) according to any one of clauses 1 to 16;
a heat dissipator (80) contacting the body main surface (20s); and va circuit board (91) on which the power semiconductor module is mounted.

### [Clause 18]

The semiconductor device according to clause 17, further including an electronic component (92-94) mounted on the circuit board (91) and located between the circuit board (91) and the module body (20).

Exemplary descriptions are given above. A person skilled in the art would recognize that the elements and methods (manufacturing processes) illustrated above to describe the technology of this disclosure can be combined with or replaced by other architectures. All replacements, variations, and modifications that fall within the scope of this disclosure and its accompanying claims are intended to be encompassed by the disclosure.

### REFERENCE SIGNS LIST

10) power semiconductor module
20) module body
20r) body back surface
20s) body main surface
21) first body side surface
22) second body side surface
23) third body side surface
24) fourth body side surface
25) first side surface
26) second side surface
27, 28) pocket
30) first terminal
301) first portion
301a) distal end
302) second portion
302a) distal end
303) third portion
303r) mounting surface
31-34) terminal
35) first internal terminal
351) internal lead
352) die pad
40) second terminal
401) first portion
401a) distal end
402) second portion
402a) distal end
403) third portion
403r) mounting surface
41, 411-418) primary terminal
42, 421-424) secondary terminal
45) second internal terminal
50) heat dissipating member
50r) back surface
50s) heat dissipating plate main surface
51-54) side surface
55) bonding portion
56) wiring pattern
61) first power semiconductor element
62) second power semiconductor element
63) first drive circuit
631) primary circuit
632) secondary circuit
64) second drive circuit
641) primary circuit
642) secondary circuit
65) resistance element
66) temperature detection resistor
70) encapsulation resin
80) heat dissipator
80s) heat dissipator main surface
81) sheet member
82) bolt
90) semiconductor device
91) circuit board
91s) board main surface
911-914) pads
92) electronic component
921) terminal
93) electronic component
931) electrode
94) electronic component
941) electrode
951-954) solder
θ1, θ2) angle
DL) length
DT) thickness
DW) width
HR) back surface height
Ll, L2) line segment
P1, P2) interval
TT) thickness
TW1, TW2) width

1. A power semiconductor module, comprising:
a module body including a power semiconductor element and a drive circuit and having a body main surface, a body back surface, a first body side surface, and a second body side surface, the body main surface facing a thickness direction, the body back surface facing a direction opposite the body main surface, the first body side surface facing a direction intersecting the thickness direction, and the second body side surface facing a direction opposite the first body side surface;
first terminals projecting from the first body side surface; and
second terminals projecting from the second body side surface; wherein
the first terminals each including a first portion extending from the first body side surface, a second portion extending downward from the first portion to below the body back surface, and a third portion extending from a lower end of the second portion and located below the body back surface; and
the second terminals each including a first portion extending from the second body side surface, a second portion extending downward from the first portion to below the body back surface, and a third portion extending from a lower end of the second portion and located below the body back surface.

2. The power semiconductor module according to claim 1, wherein the module body includes a heat dissipating member on the body main surface.

3. The power semiconductor module according to claim 1, wherein:
the second portion of each of the first terminals is inclined from the first portion so that the first body side surface becomes farther as the third portion becomes closer; and
the second portion of each of the second terminals is inclined from the first portion so that the second body side surface becomes farther as the third portion becomes closer.

4. The power semiconductor module according to claim 1, wherein the first terminals include terminals that are wider than the second terminals.

5. The power semiconductor module according to claim 1, wherein:
the first terminals are connected to the power semiconductor element; and
the second terminals are connected to the drive circuit.

6. The power semiconductor module according to claim 5, wherein:
the drive circuit includes
a primary circuit provided with a control signal for the power semiconductor element, and
a secondary circuit insulated from the primary circuit and configured to receive a signal from the primary circuit, the secondary circuit being connected to the power semiconductor element; and
the second terminals include
primary circuit terminals connected to the primary circuit, and
secondary circuit terminals connected to the secondary circuit.

7. The power semiconductor module according to claim 6, wherein:
the primary circuit terminals are arranged at equal intervals; and
an interval between the secondary circuit terminals and the primary circuit terminals is larger than the interval between the primary circuit terminals.

8. The power semiconductor module according to claim 6, wherein:
the power semiconductor element includes a first power semiconductor element and a second power semiconductor element;
the drive circuit includes a first drive circuit that is connected to the first power semiconductor element and a second drive circuit that is connected to the second power semiconductor element;
the secondary circuit terminals include a first one of the secondary circuit terminals that is connected to the secondary circuit of the first drive circuit and a second one of the secondary circuit terminals that is connected to the secondary circuit of the second drive circuit; and
the first one of the secondary circuit terminals and the second one of the secondary circuit terminals are arranged sandwiching the primary circuit terminals.

9. The power semiconductor module according to claim 1, wherein the first terminals and the second terminals each have a thickness of 0.35 mm to 1.0 mm, inclusive.

10. A semiconductor device, comprising:
the power semiconductor module according to claim 1;
a heat dissipator contacting the body main surface; and
a circuit board on which the power semiconductor module is mounted.

11. The semiconductor device according to claim 10, further comprising:
an electronic component mounted on the circuit board and located between the
circuit board and the module body.
